(19) United States
(12) Patent Application Publication
(10) Pub. No.: US 2020/0251473 A1
(43) Pub. Date: Aug. 6, 2020

(54) HIGH DENSITY FIN FIELD-EFFECT TRANSISTOR (FINFET)

(71) Applicant: QUALCOMM Incorporated, San Diego, CA (US)

(72) Inventors: Xia LI, San Diego, CA (US); Kwanyong LIM, San Diego, CA (US); Samit SENGUPTA, San Diego, CA (US)

(21) Appl. No.: 16/269,065

(22) Filed: Feb. 6, 2019

(51) Int. Cl. H01L 27/092; H01L 29/66; H01L 29/78; H01L 29/06; H01L 21/8238; H01L 21/033

(52) U.S. Cl. CPC H01L 27/0928; H01L 29/66545; H01L 29/6681; H01L 29/7851; H01L 21/0337; H01L 21/823892; H01L 21/823878; H01L 21/823828; H01L 21/823821; H01L 29/0649

(57) ABSTRACT

Certain aspects of the present disclosure generally relate to a fin-slab field-effect transistor (FET). For example, certain aspects provide a semiconductor device having a substrate, a well region disposed above the substrate, a first fin disposed above the first well region, and a second fin disposed above the first well region and adjacent to the first fin. In certain aspects, a dielectric region is disposed between the second fin and the first well region, and a first gate region is disposed adjacent to the first fin and the second fin.

### TECHNICAL FIELD

Certain aspects of the present disclosure generally relate to electronic components and, more particularly, to a fin field-effect transistor (finFET) device.

### BACKGROUND

Transistors are essential components in modern electronic devices. Large numbers of transistors are employed in integrated circuits (ICs) in many modern electronic devices. For example, components such as central processing units (CPUs) and memory systems each employ a large quantity of transistors for logic circuits and memory devices.

As electronic devices become more complex in functionality, so does the need to include a greater number of transistors in such devices. However, as electronic devices are provided in increasingly smaller packages, such as in mobile devices, for example, a greater number of transistors may be provided in a smaller IC chip. This increase in the number of transistors is achieved in part through continued efforts to miniaturize transistors in ICs. As a result, the gate lengths of transistors are reduced, thereby reducing the channel length of the transistors and interconnects. Reduced channel length in transistors has the benefit of increasing drive strength and providing smaller parasitic capacitances resulting in reduced circuit delay. However, as channel length in transistors is reduced, short channel effects (SCEs) can occur that degrade performance. More specifically, SCEs in transistors cause increased current leakage, reduced threshold voltage, and/or threshold voltage roll-off.

In this regard, to address the need to scale down channel lengths in transistors while avoiding or mitigating SCEs, transistor design alternatives have been developed. One such alternative transistor design includes a fin field-effect transistor (finFET) that provides a conducting channel via a fin formed from a substrate. Material is wrapped around the fin to form the gate of the device. The finFET includes a source and a drain interconnected by the fin such that an interior portion of the fin serves as a conduction channel between the source and drain. The fin is surrounded by a gate, and thus, the gate provides better electrostatic control over the channel, and thus helps reduce the leakage current and overcome SCEs.

### SUMMARY

Certain aspects of the present disclosure generally relate to a high density fin field-effect transistor (FET), such as a fin-slab FET.

Certain aspects provide a semiconductor device. The semiconductor device generally includes a substrate, a well region disposed above the substrate, a first fin disposed above the first well region, and a second fin disposed above the first well region and adjacent to the first fin. In certain aspects, the semiconductor device also includes a dielectric region disposed between the second fin and the first well region, and a first gate region disposed adjacent to the first fin and the second fin.

Certain aspects provide a semiconductor device. The semiconductor device generally includes a substrate and an n-type fin field-effect transistor (finFET). The n-type finFET may include a p-well (PW) region disposed above the substrate, a first fin disposed above the PW region, a second fin disposed above the PW region and adjacent to the first fin, a first dielectric region disposed between the second fin and the PW region, and a first gate region disposed adjacent to the first fin and the second fin. The semiconductor device may also include a p-type finFET having an n-well (NW) region disposed above the substrate, a third fin disposed above the NW region, a fourth fin disposed above the NW region and adjacent to the third fin, a second dielectric region disposed between the fourth fin and the NW region, and a second gate region disposed adjacent to the third fin and the fourth fin.

Certain aspects provide a method for fabricating a semiconductor device. The method generally includes forming a first fin above a substrate, growing (e.g., via an epitaxial growth process) a dummy region from a sidewall of the first fin, growing (e.g., via an epitaxial growth process) a second fin from a sidewall of the dummy region, and forming a first gate region adjacent to the first fin and the second fin.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIGS. 1A and 1B illustrate example operations for fabricating a high density fin field-effect transistor (finFET) device, in accordance with certain aspects of the present disclosure.

FIGS. 2A and 2B illustrate a cross-section and top view, respectively, of a high density finFET device, in accordance with certain aspects of the present disclosure.

FIG. 2C illustrates an example finFET device having n-type and p-type single-fin FETs adjacent to fin-slab FETs having side fins disposed above a dielectric region, in accordance with certain aspects of the present disclosure.

FIG. 3 illustrates an example finFET device having side fins with portions having different doping types, in accordance with certain aspects of the present disclosure.

FIGS. 4A and 4B illustrate a top view and a cross-section, respectively, of an example finFET device having n-type and p-type single-fin FETs adjacent to fin-slab FETs, in accordance with certain aspects of the present disclosure.

FIGS. 5A-5F illustrate example operations for fabricating a finFET device, in accordance with certain aspects of the present disclosure.

FIG. 6 is a flow diagram illustrating example operations for fabricating a semiconductor device, in accordance with certain aspects of the present disclosure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Transistor

Although a fin field-effect transistor (finFET) reduces leakage current and avoids or mitigates short channel effects (SCEs) compared to planar transistors, integrated circuits (ICs) employing finFETs continue to benefit from increased performance. For example, an IC may include one or more complementary metal-oxide semiconductor (CMOS) circuits that employ p-type and n-type finFETs. Conventional fabrication processes can result in p-type and n-type finFETs having varying performance characteristics, such that either the p-type finFET or the n-type finFET reduces the performance of a corresponding CMOS circuit, reducing the performance of the IC. In this manner, it would be advantageous to fabricate p-type and n-type finFETs so as to reduce or avoid performance degradations attributable to conventional fabrication processes.

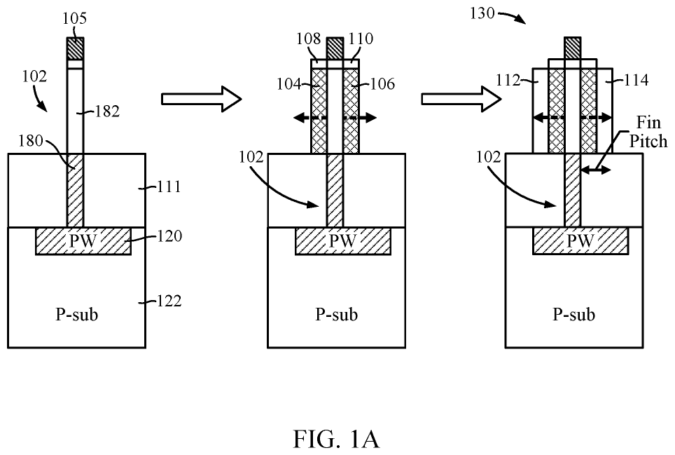

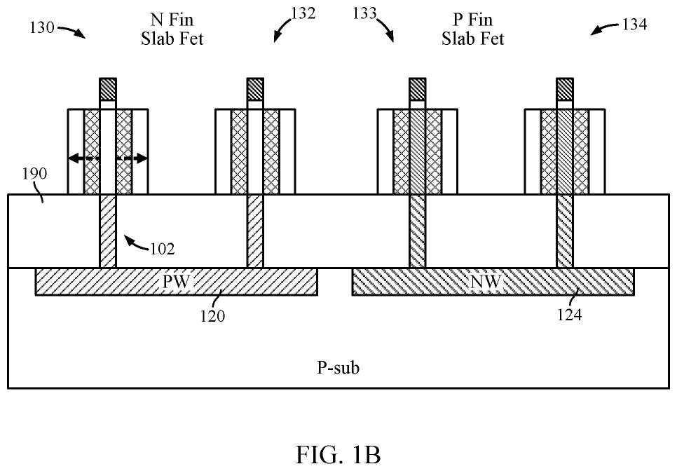

Certain aspects of the present disclosure provide a high density finFET device, and a fabrication process for the high density finFET device, with improved characteristics. For example, the present disclosure provides a vertical gate all-around (GAA) fin-slab FET device having a reduced fin pitch and fin height as compared to conventional implementations. Fin pitch refers to a distance between sidewalls of adjacent fins, as illustrated in FIG. 1A. Conventional lithography and etching processes used for fabricating a finFET may limit fin pitch. As a result, the fin height of the finFET may be increased to achieve a reduced fin pitch. Certain aspects of the present disclosure provide a high density finFET having a fin pitch that is not limited by lithography and etching processes, allowing a fin pitch that is smaller than 16 nm and a lower fin height as compared to conventional finFET devices.

FIGS. 1A and 1B illustrate example operations for fabricating a finFET device, in accordance with certain aspects of the present disclosure. As illustrated, a p-well (PW) region 120 may be formed above a p-type substrate 122 (P-sub). A center fin 102 may be formed above the PW region 120, with a hard mask layer 105 above the center fin 102. The center fin 102 may comprise silicon (Si), for example. Then, dummy regions 104, 106 may be formed via epitaxial growth adjacent to the fin 102 above a dielectric region 111, as illustrated. The dummy regions 104, 106 may comprise silicon germanium (SiGe), for example. As illustrated, the center fin 102 includes a p-type portion 180 and a p-type portion 182. The p-type portion 180 may have a different doping concentration as compared to the p-type portion 182. An oxide hard mask 108, 110 may be formed above each of the dummy regions 104, 106. Side fins 112, 114 may then be formed adjacent to the dummy regions 104, 106 via epitaxial growth to form the fin-slab 130. The side fins 112, 114 may comprise the same material as the center fin 102 (e.g., Si). This process may be repeated to form more than two side fins (e.g., four, six, or more side fins).

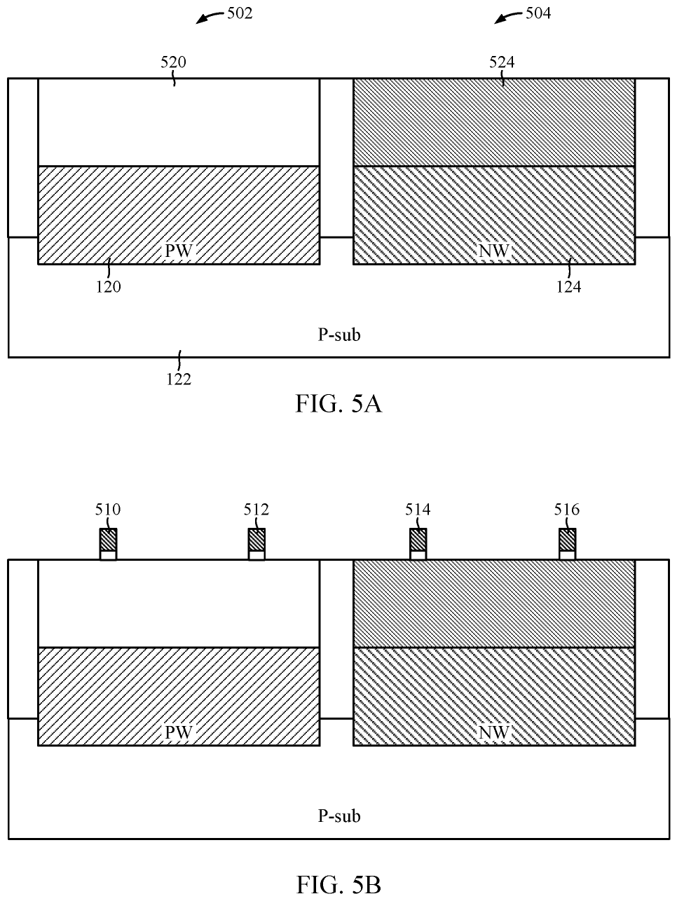

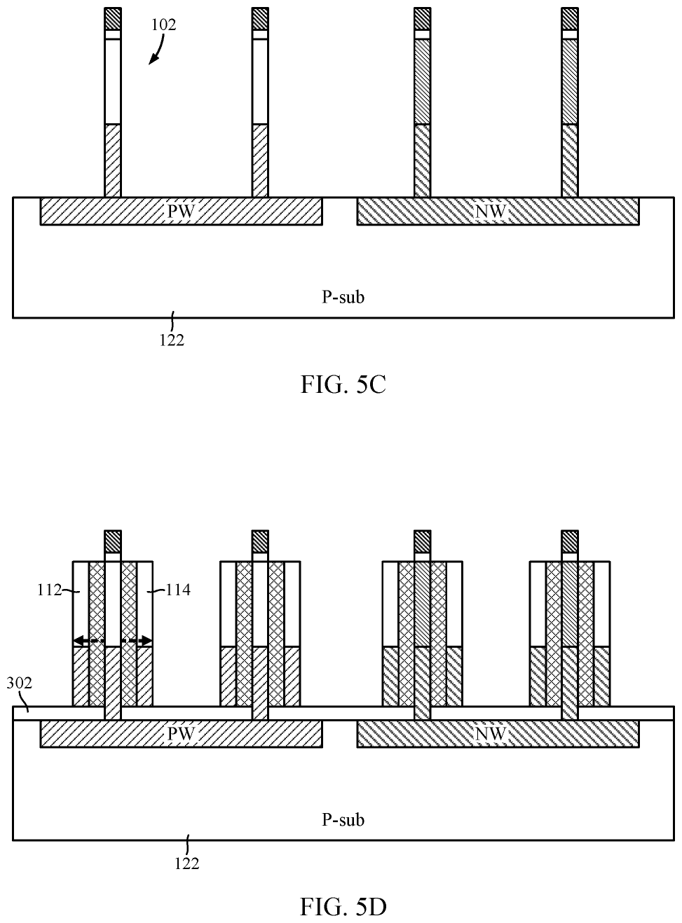

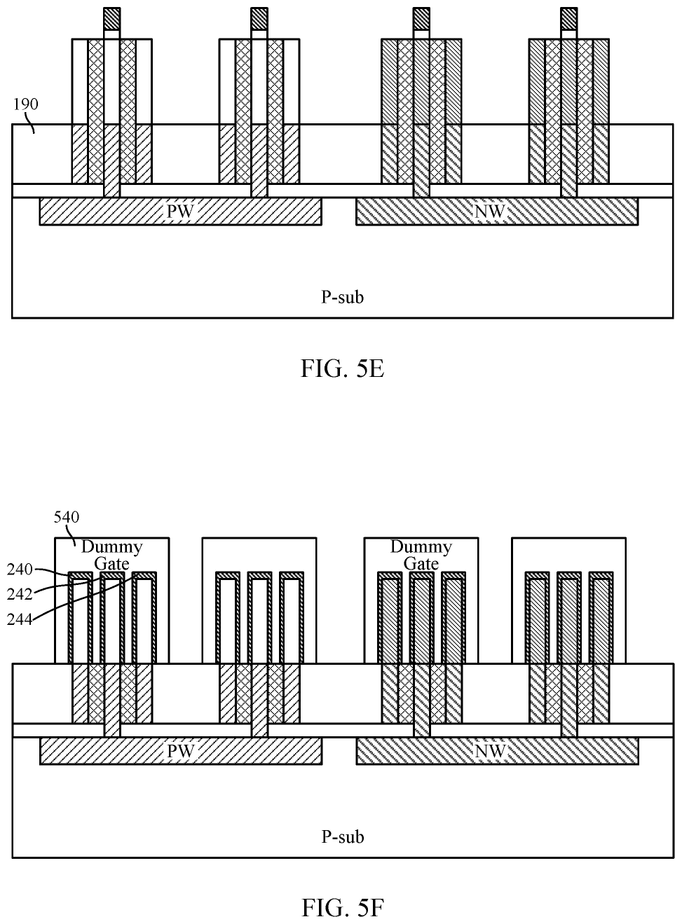

In certain aspects, fin slabs may be formed above both PW and n-well (NW) regions to form both n-type and p-type fin-slab FETs, as illustrated in FIG. 1B. As used herein, a fin slab generally refers to a main fin with one or more side fins adjacent to lateral surfaces of the main fin. For example, fin slabs 130, 132 may be formed above the PW region 120, and fin slabs 134, 136 may be formed above the NW region 124. The fabrication of the n-type and p-type fin-slab FETs are described in more detail herein with respect to FIGS. 5A-5F.

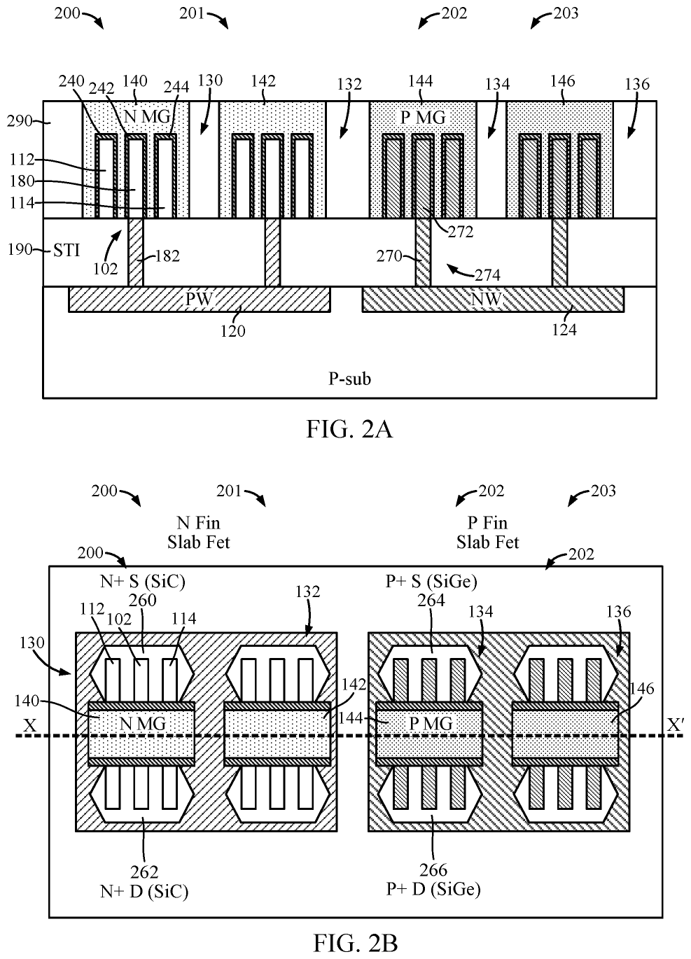

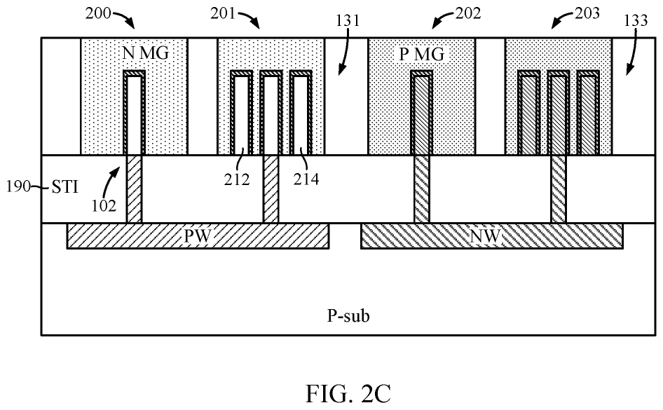

FIGS. 2A and 2B illustrate a cross-section and top view, respectively, of a high density finFET device, in accordance with certain aspects of the present disclosure. FIG. 2A is a cross-section taken through line X-X′ in FIG. 2B. The finFET device includes n-type finFETs 200, 201 and p-type finFETs 202, 203. Each of the n-type finFETs 200, 201 and the p-type finFETs 202, 203 are implemented as fin-slab FETs, as described herein.

As illustrated in FIG. 2A, n-type gate regions 140, 142 may be formed around the fins of each of the fin-slabs 130, 132, and p-type gate regions 144, 146 may be formed around the fins of each of the fin-slabs 134, 136. Dielectric regions (e.g., dielectric regions 240, 242, 244) may be implemented between the gate regions (e.g., gate region 140) to electrically isolate the gate regions from the fin-slabs. In certain aspects, the side fins (e.g., fins 112, 114) of the fin slabs may be implemented above a shallow trench isolation (STI) region 190, as illustrated in FIG. 2A. In certain aspects, one or more fins of the fin slabs include portions of different doping concentrations. For example, the center fin 102 includes a p-type portion 180 and a p-type portion 182, and the center fin 274 includes an n-type portion 270 and an n-type portion 272. The p-type portion 180 may have a different doping concentration as compared to the p-type portion 182, and the n-type portion 270 may have a different doping concentration as compared to the n-type portion 272.

In certain aspects, the gate regions 140, 142, 144, 146 may be implemented as metal gates (MGs). The gate regions 140, 142, 144, 146 may be adjacent to an interlayer dielectric (ILD) region 290. As illustrated in FIG. 2B, source and drain regions may be implemented adjacent to the fins of each of the fin slabs 130, 132, 134, 136. For example, an N+ source region 260 and an N+ drain region 262 may be implemented adjacent to fins 102, 112, 114. The source region 260 and the drain region 262 may be implemented using silicon carbide (SiC), for example. Moreover, a P+ source region 264 and a P+ drain region 266 may be implemented adjacent to the fin slab 134 of the p-type finFET 202. The source region 264 and drain region 266 may be implemented using silicon germanium (SiGe), for example.

FIG. 2C illustrates an example finFET device having n-type and p-type single-fin FETs adjacent to fin-slab FETs and having side fins disposed above an STI region, in accordance with certain aspects of the present disclosure. In other words, the finFET 200 and the finFET 202 may be implemented with a single fin (e.g., fin 102). Moreover, the side fins (e.g., fins 212, 214) of each of the fin slabs 131, 133 are disposed above the STI region 190 and may have a single doping type.

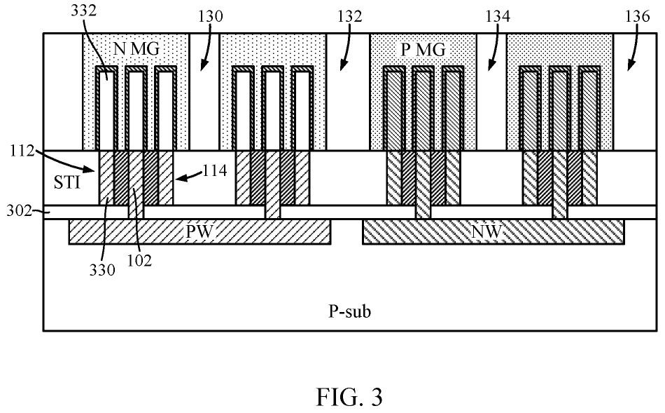

FIG. 3 illustrates an example finFET device having side fins with portions having different doping types, in accordance with certain aspects of the present disclosure. For example, the fins 112, 114 of the fin slab 130 are disposed above the dielectric layer 302, and include p-type portions. For example, fin 112 includes a p-type portion 330 and a p-type portion 332. The p-type portion 330 may have a different doping concentration as compared to the p-type portion 332.

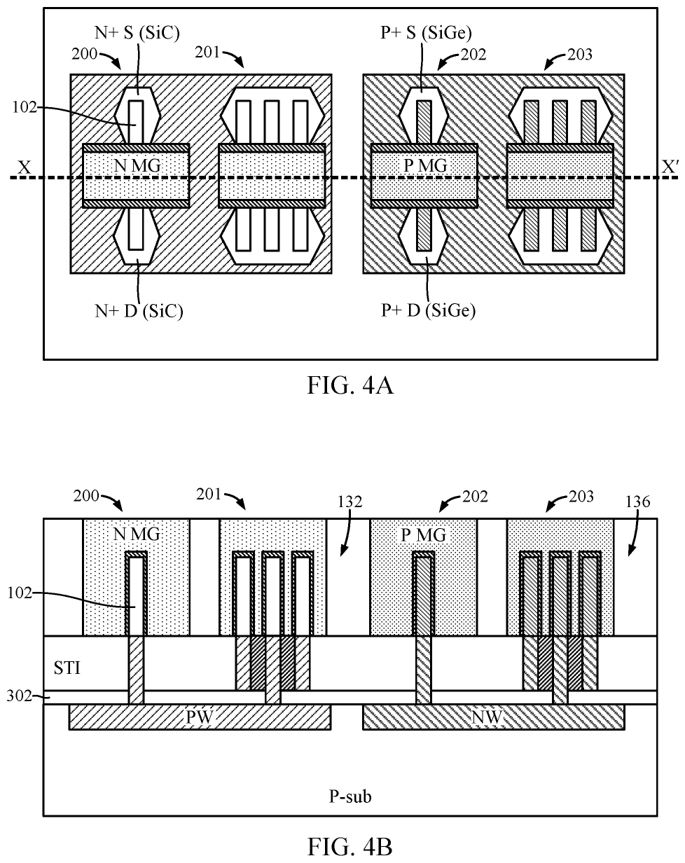

FIGS. 4A and 4B illustrate a top view and cross-section, respectively, of an example finFET device having n-type and p-type single-fin FETs adjacent to fin-slab FETs, in accordance with certain aspects of the present disclosure. FIG. 4B is a cross-section taken through line X-X′ in FIG. 4A. For example, the n-type finFET 200 and the p-type finFET 202 are implemented with a single fin (e.g., fin 102 of the n-type finFET 200). Moreover, the side fins of the fin slabs 132, 136 include portions having different doping types, as illustrated.

FIGS. 5A-5F illustrate example operations for fabricating a finFET device, in accordance with certain aspects of the present disclosure. Separate photo resist (PR) opening of N or P finFET areas may be formed, followed by implantation of the PW region 120 and P− semiconductor region 520 for the n-type fin device 502 and implantation of the NW region 124 and N− semiconductor region 524 for the p-type fin device 504. PR ashing, stripe, and cleaning of the finFET device are then performed. As illustrated in FIG. 5B, silicon nitride (SiN) fin hard mask regions 510, 512, 514, 516 are formed by a spacer etch back process. As illustrated in FIG. 5C, fin etching is performed to form center fins, such as the fin 102. The width of each of the fins (e.g., fin 102) may be about 10 nm.

As illustrated in FIG. 5D, a thin oxide layer (e.g., dielectric layer 302) may be deposited above substrate 122 to prevent bottom epitaxial growth. The sidewalls of the fins (e.g., fin 102) are then cleaned, followed by a sidewall epitaxial growth process to form the side fins (e.g., side fins 112, 114), as described with respect to FIG. 1A. Oxide is then deposited adjacent to the fins, followed by CMP of the oxide. The oxide is then recessed to form the STI region 190, as illustrated in FIG. 5E.

In certain aspects, instead of forming the thin oxide layer (e.g., dielectric layer 302) as described with respect to FIG. 5D, STI region 190 is formed prior to the epitaxial growth to form the fin sidewalls, as illustrated in FIG. 1B. In this case, the fin sidewalls are disposed over the STI region 190, as opposed to the dielectric layer 302.

As illustrated in FIG. 5F, the dummy regions (e.g., dummy regions 104, 106 described with respect to FIG. 1A) between the fins (e.g., fins 102, 112) are removed, followed by the deposition or growth of gate dielectric regions 240, 242, 244, and the deposition and patterning of dummy poly gates (e.g., dummy gate 540). Source and drain regions (e.g., source regions 260, 264 and drain regions 262, 266 as described with respect to FIG. 2B) may also be formed at this stage. Oxide is then deposited to form the ILD region 290, followed by CMP of the ILD region 290. The dummy gates are then separately removed and cleaned, followed by the deposition of high-k (HK) dielectric and metal to form the gate regions 140, 142, 144, 146 to form the finFET device described with respect to FIG. 2A.

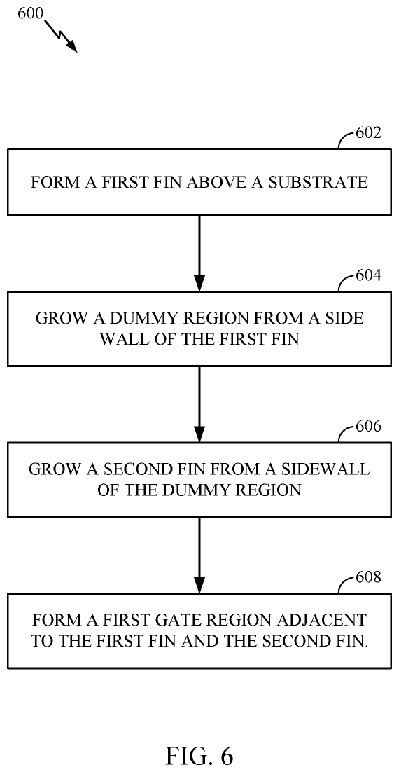

FIG. 6 is a flow diagram illustrating example operations 600 for fabricating a semiconductor device, in accordance with certain aspects of the present disclosure. The operations 600 may be performed by a semiconductor fabrication chamber, for example.

The operations 600 begin, at block 602, with the chamber forming a first fin (e.g., fin 102) above a substrate (e.g., substrate 122). At block 604, an epitaxial growth process or any other suitable growth process(es) may be used to grow a dummy region (e.g., dummy region 104) from a sidewall of the first fin, and at block 606, grow a second fin from a sidewall of the dummy region. In certain aspects, at block 608, the chamber may form a first gate region adjacent to the first fin and the second fin.

In certain aspects, the operations 600 also include the chamber removing the dummy region. In this case, the first gate region is formed adjacent to the first fin and the second fin after the dummy region is removed. In certain aspects, the operations 600 also include the chamber forming a dielectric layer (e.g., dielectric layer 302 or STI region 190). The dummy region and the second fin may be formed (e.g., via an epitaxial growth process) above the dielectric layer.

In certain aspects, the operations 600 also include the chamber forming a well region (e.g., PW region 120) and forming a semiconductor region (e.g., semiconductor region 520) above the well region. The semiconductor region and the well region may have different doping concentrations. In this case, the operations 600 also include the chamber forming a hard mask (e.g., hard mask region 510) above the semiconductor region and the well region, the first fin being formed by etching a portion of the semiconductor region that is not disposed below the hard mask. In certain aspects, the first fin is further formed by etching a portion of the well region that is not disposed below the hard mask.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

1. A semiconductor device comprising:
a substrate;
a first well region disposed above the substrate;
a first fin disposed above the first well region;
a second fin disposed above the first well region and adjacent to the first fin;
a dielectric region disposed between the second fin and the first well region, the second fin being above the dielectric region and the first well region, the dielectric region separating the second fin from the first well region; and
a first gate region disposed adjacent to the first fin and the second fin.

2. The semiconductor device of claim 1, wherein the first fin comprises a first region and a second region, and wherein the first region has a different doping concentration than the second region.

3. The semiconductor device of claim 2, wherein the second fin comprises a third region and a fourth region, and wherein the third region has a different doping concentration than the fourth region.

4. The semiconductor device of claim 1, further comprising:
a first dielectric layer disposed between the first gate region and the first fin; and
a second dielectric layer disposed between the first gate region and the second fin.

5. The semiconductor device of claim 1, wherein a portion of the first gate region is disposed between the first fin and the second fin.

6. The semiconductor device of claim 1, further comprising:
a third fin disposed above the first well region, wherein the first gate region is further disposed adjacent to the third fin and wherein the dielectric region is disposed between the third fin and the first well region.

7. The semiconductor device of claim 6, wherein the second fin is disposed adjacent to a first side of the first fin, and wherein the third fin is disposed adjacent to a second side of the first fin, the first side and the second side being opposite sides of the first fin.

8. The semiconductor device of claim 1, further comprising:
a third fin disposed above the first well region; and
a second gate region disposed adjacent to the third fin.

9. The semiconductor device of claim 1, further comprising:
a second well region disposed above the substrate and having a different doping concentration than the first well region;
a third fin disposed above the second well region;
a fourth fin disposed above the second well region and adjacent to the third fin, wherein the dielectric region is disposed between the fourth fin and the second well region; and
a second gate region disposed adjacent to the third fin and the fourth fin.

10. The semiconductor device of claim 1, wherein the first gate region comprises a metal gate region.

11. The semiconductor device of claim 1, further comprising:
a drain region disposed adjacent to the first fin and the second fin; and
a source region disposed adjacent to the first fin and the second fin.

12. The semiconductor device of claim 11, wherein the first fin comprises silicon, germanium, or a group III/V semiconductor.

13. A semiconductor device comprising:
a substrate;
an n-type fin field-effect transistor (finFET), comprising:
a p-well (PW) region disposed above the substrate;
a first fin disposed above the PW region;
a second fin disposed above the PW region and adjacent to the first fin;
a first dielectric region disposed between the second fin and the PW region, the second fin being above the first dielectric region and the PW region, the first dielectric region separating the second fin from the PW region; and
a first gate region disposed adjacent to the first fin and the second fin; and
a p-type finFET, comprising:
an n-well (NW) region disposed above the substrate;
a third fin disposed above the NW region;
a fourth fin disposed above the NW region and adjacent to the third fin;
a second dielectric region disposed between the fourth fin and the NW region, the fourth fin being above the second dielectric region and the NW region, the second dielectric region separating the fourth fin from the NW region; and
a second gate region disposed adjacent to the third fin and the fourth fin.

14. The semiconductor device of claim 13, wherein:
the first fin comprises a first p-type portion and a second p-type portion, the first p-type portion being above the second p-type portion; and
the third fin comprises a third p-type portion and a fourth p-type portion, the third p-type portion being above the fourth p-type portion.

15. The semiconductor device of claim 14, wherein:
the second fin comprises a fifth p-type portion and a sixth p-type portion, the fifth p-type portion being above the sixth p-type portion.
the fourth fin comprises a seventh p-type portion and an eighth p-type portion, the seventh p-type portion being above the eighth p-type portion.

16. A method for fabricating a semiconductor device, comprising:
forming a first fin above a substrate;
growing a dummy region from a sidewall of the first fin;
growing a second fin from a sidewall of the dummy region; and
forming a first gate region adjacent to the first fin and the second fin.

17. The method of claim 16, further comprising:
removing the dummy region, wherein the first gate region is formed adjacent to the first fin and the second fin after the dummy region is removed.

18. The method of claim 16, further comprising:
forming a dielectric layer, wherein the dummy region and the second fin are formed, via an epitaxial growth process, above the dielectric layer.

19. The method of claim 16, further comprising:
forming a well region;
forming a semiconductor region above the well region, the semiconductor region and the well region having different doping concentration; and
forming a hard mask above the semiconductor region and the well region, wherein the first fin is formed by etching a portion of the semiconductor region that is not disposed below the hard mask.

20. The method of claim 19, wherein the first fin is further formed by etching a portion of the well region that is not disposed below the hard mask.
